(19) United States
(12) Patent Application Publication
(10) Pub. No.: US 2016/0017480 A1
(43) Pub. Date: Jan. 21, 2016

(54) LAYERED STRUCTURE WITH PATTERN AND PROCESS OF MANUFACTURING SAME

(71) Applicants: Kung-Cheng Chen, Taichung City (TW); Lung-Chuan Huang, Taichung City (TW); Chung-Ping Tung, Taichung City (TW)

(72) Inventors: Kung-Cheng Chen, Taichung City (TW); Lung-Chuan Huang, Taichung City (TW); Chung-Ping Tung, Taichung City (TW)

(21) Appl. No.: 14/332,915

(22) Filed: Jul. 16, 2014

(51) Int. Cl. C23C 14/12; B41M 1/26; C23C 14/58

(52) U.S. Cl. CPC C23C 14/12; C23C 14/588; B41M 1/26

(57) ABSTRACT

A layered structure is provided with a substrate including a first uneven surface on a top surface; a first coat layer having a predetermined color pattern and disposed on a top surface of the substrate; and a first material transfer layer having a predetermined inked pattern and disposed on a top surface of the first coat layer. A CNC machine is used to render the top surface of the substrate colorful.

### BACKGROUND OF THE INVENTION

1. Field of the Invention

The invention relates to a layered structure on an object and more particularly to a layered structure with pattern and a process of manufacturing same by using a computer numerical control (CNC) machine so that surface of the object can be colorful.

2. Description of Related Art

Conventionally, coating and/or spraying are performed on surface of an object (e.g., cabinet) made of plastic, aluminum alloy, or steel. Also, a pattern is formed on the surface of the object so as to render the object visually attractive.

However, the processes are time consuming and low in performance, and the pattern of one object may be different from that of another object after the processes. It is often that the object is discarded due to failure.

Thus, the need for improvement still exists.

### SUMMARY OF THE INVENTION

It is therefore one object of the invention to provide a layered structure comprising a substrate including a first uneven surface on a top surface; a first coat layer having a predetermined color pattern and disposed on a top surface of the substrate; and a first material transfer layer having a predetermined inked pattern and disposed on a top surface of the first coat layer. A CNC machine is used to render the top surface of the substrate colorful.

It is another object of the invention to provide a process of manufacturing a layered structure, comprising the steps of (a) preparing a substrate which is aluminum alloy, magnesium alloy, or plastic; (b) using a CNC (computer numerical control) machine to move a metal brush along a predetermined direction to rub a top surface of the substrate to form a first uneven surface on the top surface of the substrate wherein hardness of the metal brush is greater than that of the substrate, and the metal brush is made of high hardness material which is alloy steel or tool steel; (c) using the CNC machine to control a coating device for coating a first coat layer on the top surface of the substrate wherein the first coat layer has a predetermined color pattern; (d) drying the first coat layer; (e) using the CNC machine to move the metal brush along a predetermined direction to rub a top surface of the coat layer to form a first uneven surface on the top surface of the substrate; (f) using the CNC machine to dispose a first material transfer layer having a predetermined inked pattern on the top surface of the coat layer; (g) drying the first material transfer layer at a temperature of 100-150° C. for about 30 minutes; (h) repeating steps (c) to (g) to form a second coat layer and a second material transfer layer sequentially; and (i) performing QC (quality control), packaging, and shipping.

The above and other objects, features and advantages of the invention will become apparent from the following detailed description taken with the accompanying drawings.

### BRIEF DESCRIPTION OF THE DRAWINGS

FIG. 1 is a longitudinal sectional view of a layered structure with pattern according to a first preferred embodiment of the invention;

FIG. 2 is flow chart illustrating a process of manufacturing a layered structure with pattern according to the invention;

FIG. 3 is a longitudinal sectional view of a layered structure with pattern according to a second preferred embodiment of the invention;

FIG. 4 is a longitudinal sectional view of a layered structure with pattern according to a third preferred embodiment of the invention;

FIG. 5 is a longitudinal sectional view of a layered structure with pattern according to a fourth preferred embodiment of the invention;

FIG. 6 is a longitudinal sectional view of a layered structure with pattern according to a fifth preferred embodiment of the invention;

FIG. 7 is a longitudinal sectional view of a layered structure with pattern according to a sixth preferred embodiment of the invention;

FIG. 8 is a longitudinal sectional view of a layered structure with pattern according to a seventh preferred embodiment of the invention; and

FIG. 9 is a longitudinal sectional view of a layered structure with pattern according to an eighth preferred embodiment of the invention.

### DETAILED DESCRIPTION OF THE INVENTION

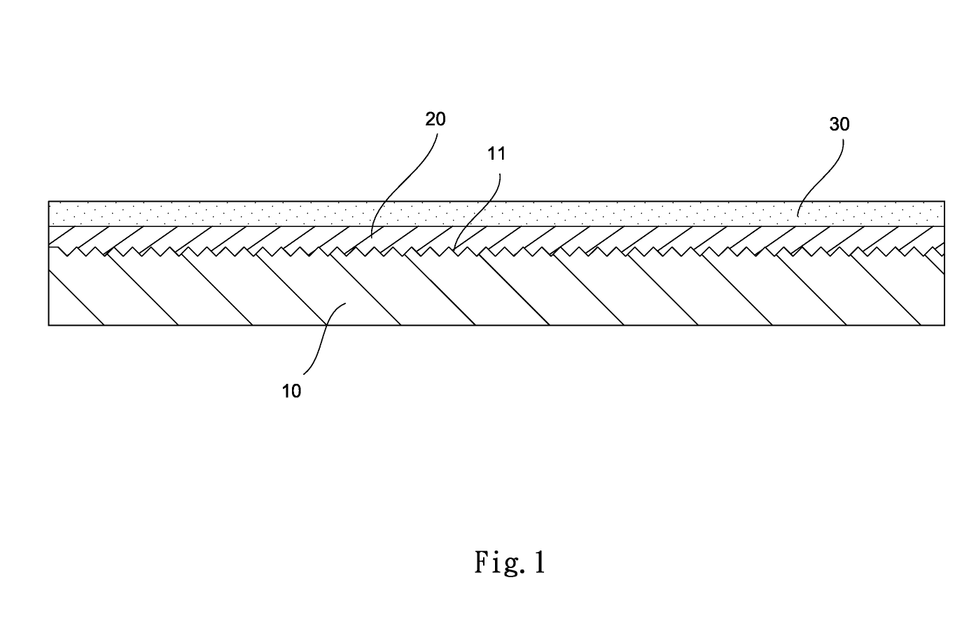

Referring to FIG. 1, a layered structure with pattern in accordance with a first preferred embodiment of the invention comprises the following components as discussed in detail below.

A substrate 10, a first coat layer 20, and a first material transfer layer 30 are provided. The coat layer 20 has a thickness of about several micrometers. The first coat layer 20 has a predetermined color pattern. The first coat layer 20 can be PU (polyurethane) or PMMA (Polymethylmethacrylate). The first coat layer 20 is provided on the substrate 10. The first material transfer layer 30 is provided on the first coat layer 20. The first material transfer layer 30 has a predetermined inked pattern.

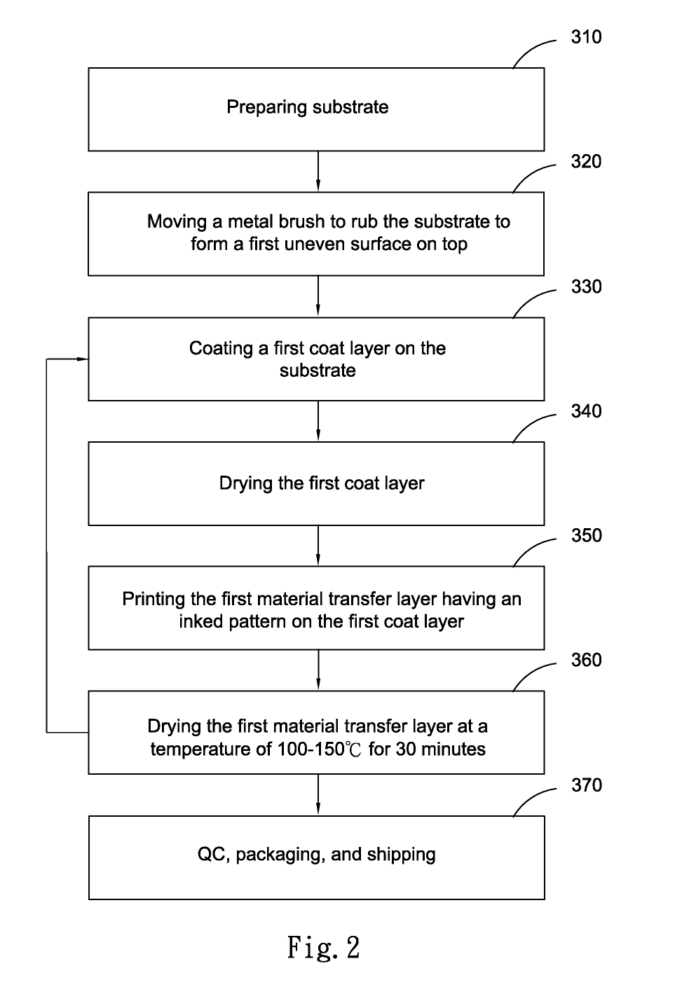

Referring to FIG. 2 in conjunction with FIG. 1, a process of manufacturing a layered structure with a pattern in accordance with the invention is illustrated. A CNC (computer numerical control) machine is employed to perform the process. The process comprises the following steps:

Step 310: A substrate 10 is prepared for being colored. The substrate 10 is a material selected from aluminum alloy, magnesium alloy, or plastic.

Step 320: A metal brush is used to move along a predetermined direction to rub a top surface of the substrate 10 so as to form a first uneven surface 11. Hardness of the metal brush is greater than that of the substrate 10. Preferably, the metal brush is made of high hardness material such as alloy steel or tool steel. Preferably, washing is done on the substrate 10 for removing solution and oil remained after the rubbing.

Step 330: A coating device is used to coat a first coat layer 20 on the substrate 10 by using PVD (physical vapor deposition) or CVD (chemical vapor deposition). Thickness of the first coat layer 20 can be increased or decreased depending on requirements. Irregularities (e.g., projections and/or cavities) on the surface of the substrate 10 can be covered by increasing thickness of the first coat layer 20 printed on the substrate 10 so as to be visually aesthetic.

Step 340: The first coat layer 20 is dried for about 30 minutes. Temperature for drying the first coat layer 20 is about 180° C. if the first coat layer 20 is PU. Alternatively, temperature for drying the first coat layer 20 is about 90-180° C. if the first coat layer 20 is PMMA.

Step 350: An activation agent is sprayed on the first coat layer 20. Next, the first material transfer layer 30 is printed on the first coat layer 20 in a covering relationship by using water-based printing technology so that the substrate can be colorful.

Step 360: The first material transfer layer 30 is dried at a temperature of 100-150° C. for about 30 minutes. It is noted that the number of the first coat layer 20 and/or the number of the first material transfer layer 30 can be changed depending on requirements. Further, the first material transfer layer 30 may be disposed under the first coat layer 20 depending on requirements.

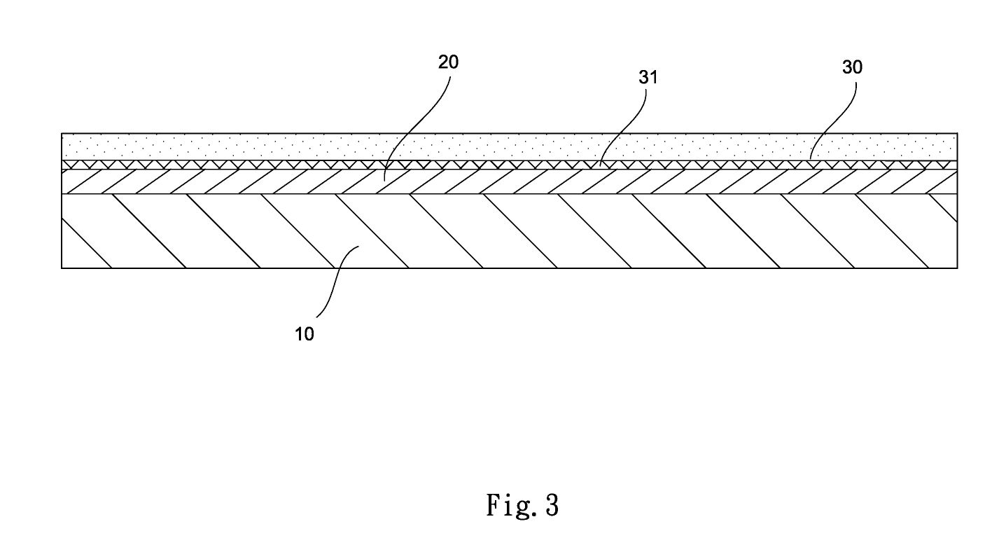

Step 370: QC (quality control), packaging, and shipping are done. Referring to FIG. 3, a layered structure with pattern in accordance with a second preferred embodiment of the invention is shown. The characteristics of the second preferred embodiment are substantially the same as that of the first preferred embodiment except the following:

In step 350, an adhesive layer 31 is coated on the bottom of the first material transfer layer 30. Further, the first material transfer layer 30 is adhered to the first coat layer 20 by using thermal printing technology. The ink in the first material transfer layer 30 may deposit the predetermined inked pattern on the first coat layer 20 and change color of the first coat layer 20. Finally the first material transfer layer 30 can be released to render the top surface of the substrate 10 colorful.

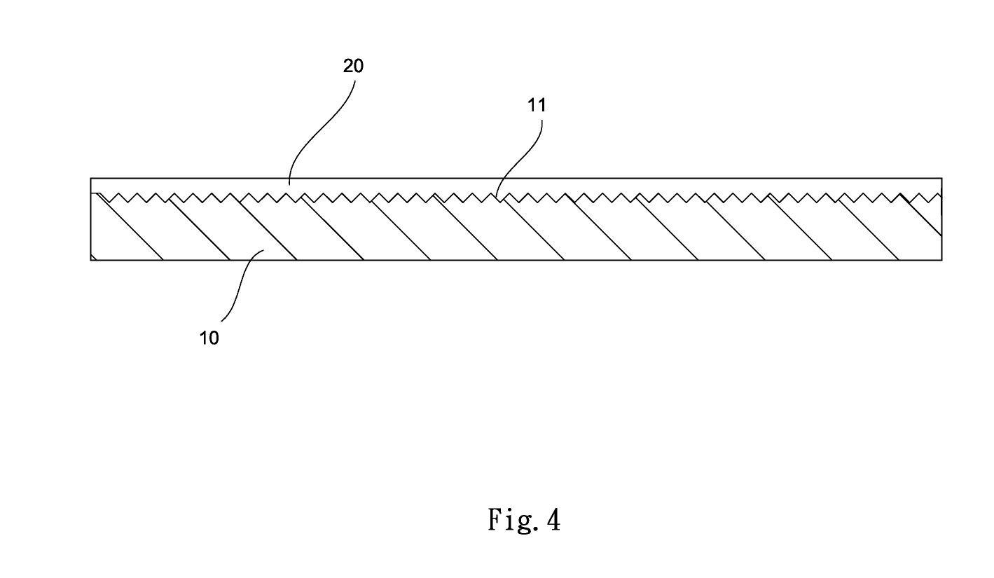

Referring to FIG. 4, a layered structure with pattern in accordance with a third preferred embodiment of the invention is shown. The characteristics of the third preferred embodiment are substantially the same as that of the first preferred embodiment except the following:

After polishing the substrate 10, coating the first coat layer 20 on the substrate 10 is performed. Next, drying is performed. Finally, QC, packaging, and shipping are performed.

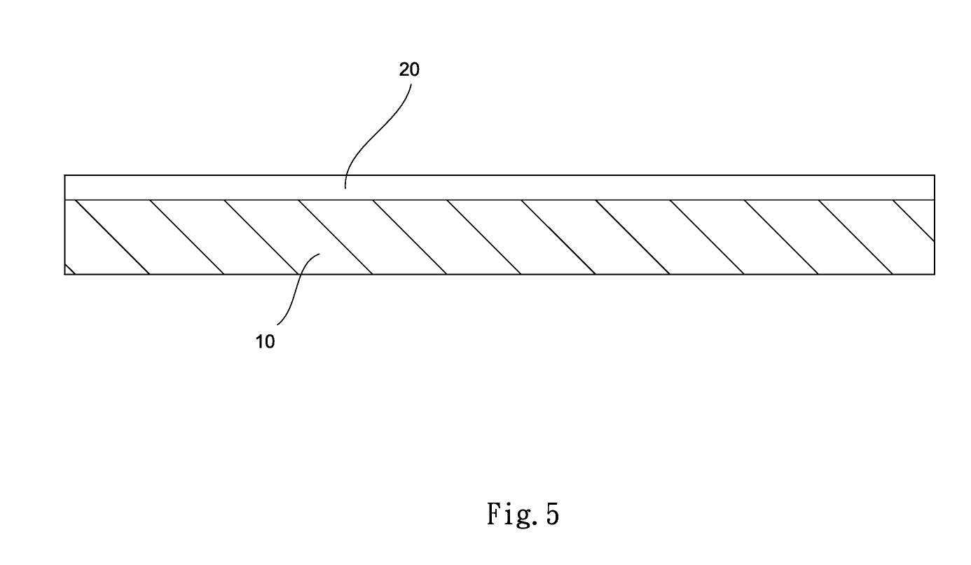

Referring to FIG. 5, a layered structure with pattern in accordance with a fourth preferred embodiment of the invention is shown. The characteristics of the fourth preferred embodiment are substantially the same as that of the first preferred embodiment except the following:

After coating the first coat layer 20 on the substrate 10, drying is performed. Finally, QC, packaging, and shipping are done.

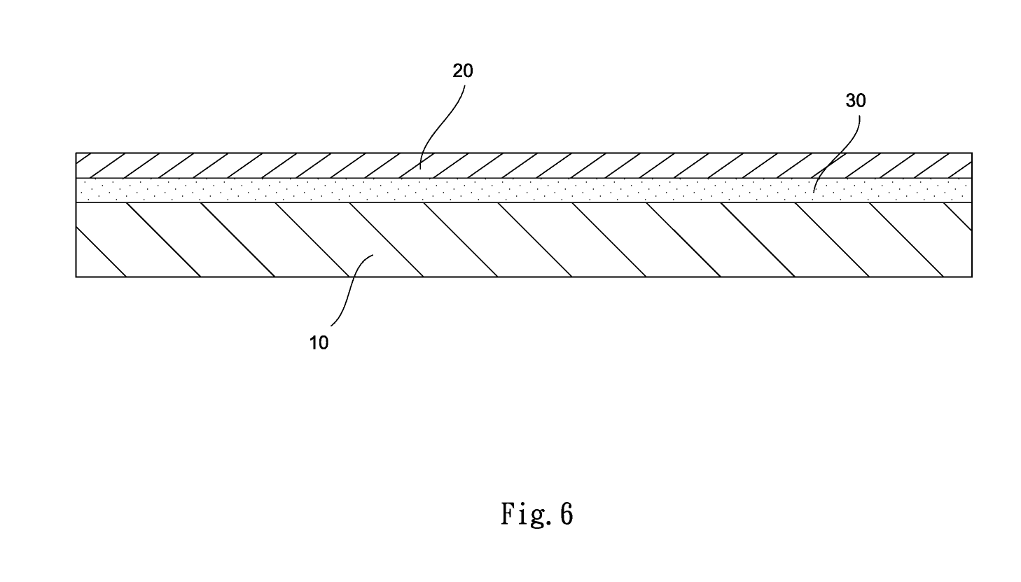

Referring to FIG. 6, a layered structure with pattern in accordance with a fifth preferred embodiment of the invention is shown. The characteristics of the fifth preferred embodiment are substantially the same as that of the first preferred embodiment except the following:

After printing the first material transfer layer 30 on the substrate 10, drying is performed. Next, the first coat layer 20 is coated on the first material transfer layer 30. Next, drying is performed. Finally, QC, packaging, and shipping are done.

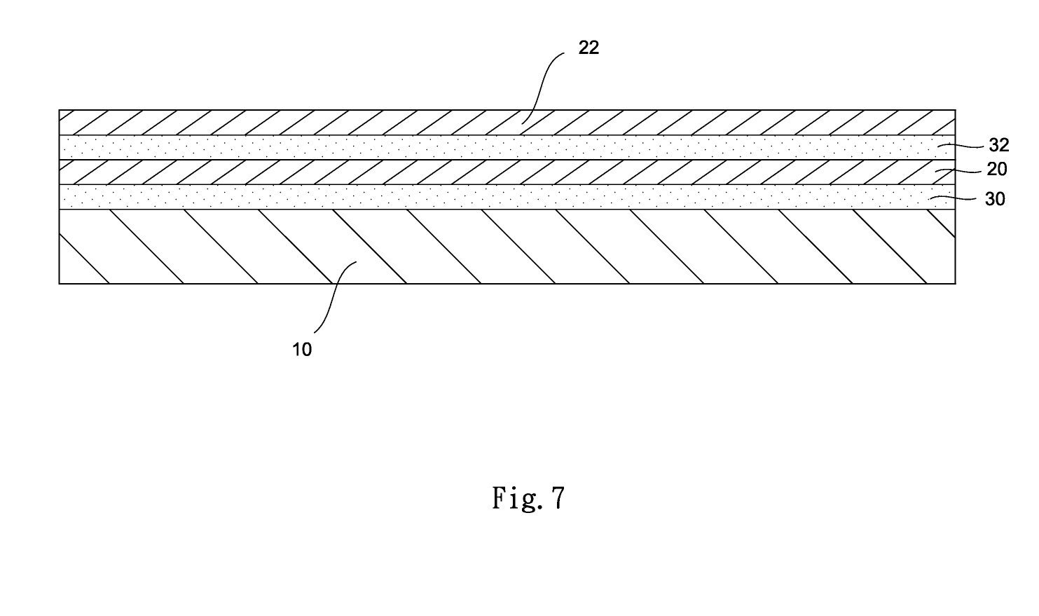

Referring to FIG. 7, a layered structure with pattern in accordance with a sixth preferred embodiment of the invention is shown. The characteristics of the sixth preferred embodiment are substantially the same as that of the fifth preferred embodiment except the following:

The first material transfer layer 30 is formed on the substrate 10, the first coat layer 20 is formed on the first material transfer layer 30, a second material transfer layer 32 is formed on the first coat layer 20, and a second coat layer 22 formed on the first material transfer layer 32.

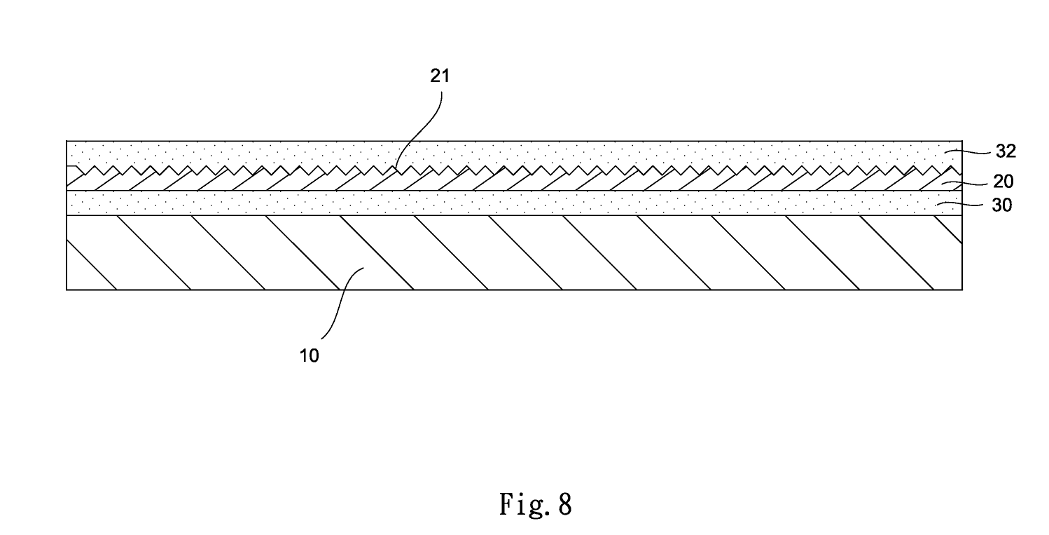

Referring to FIG. 8, a layered structure with pattern in accordance with a seventh preferred embodiment of the invention is shown. The characteristics of the seventh preferred embodiment are substantially the same as that of the sixth preferred embodiment except the following:

The first material transfer layer 30 is formed on the substrate 10, the first coat layer 20 is formed on the first material transfer layer 30, and a first material transfer layer 32 is formed on the first coat layer 20. Further, top of the first coat layer 20 is rubbed to form a second uneven surface 21.

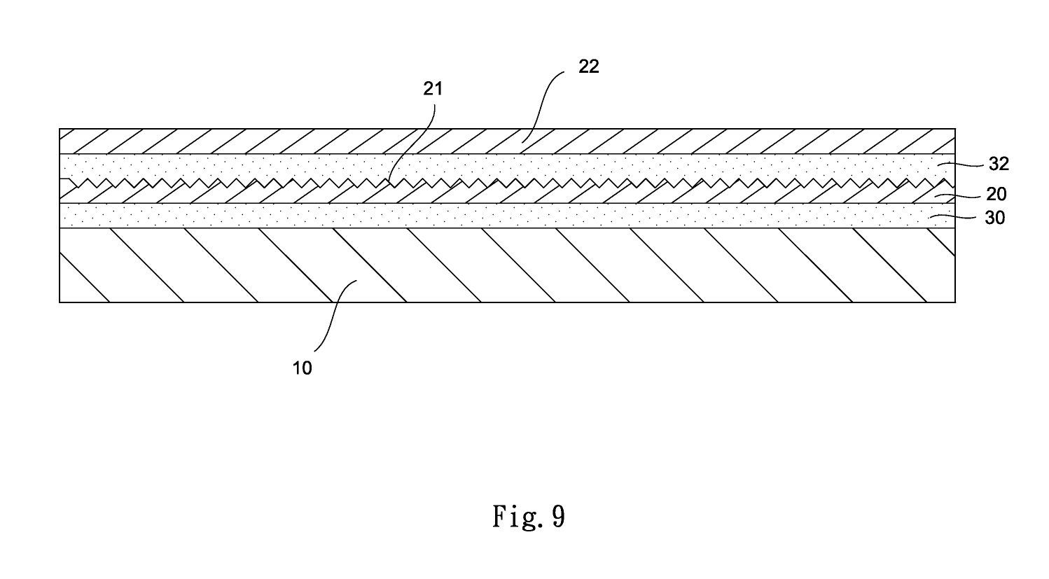

Referring to FIG. 9, a layered structure with pattern in accordance with an eighth preferred embodiment of the invention is shown. The characteristics of the eighth preferred embodiment are substantially the same as that of the sixth preferred embodiment except the following:

Top of the first coat layer 20 is rubbed to a second uneven surface 21. While the invention has been described in terms of preferred embodiments, those skilled in the art will recognize that the invention can be practiced with modifications within the spirit and scope of the appended claims.

What is claimed is:

1. A layered structure comprising:
a substrate including a first uneven surface on a top surface;
a first coat layer having a predetermined color pattern and disposed on a top surface of the substrate; and
a first material transfer layer having a predetermined inked pattern and disposed on a top surface of the first coat layer;
wherein a CNC (computer numerical control) machine is used to render the top surface of the substrate colorful.

2. The layered structure of claim 1, wherein the first coat layer is formed on the top surface of the substrate by using PVD (physical vapor deposition) or CVD (chemical vapor deposition), and wherein thickness of the first coat layer can be increased or decreased depending on requirements.

3. The layered structure of claim 1, wherein the first coat layer is PU (polyurethane) and the first coat layer is dried at a temperature of about 180° C. for about 30 minutes.

4. The layered structure of claim 1, wherein the first coat layer is PMMA (Polymethylmethacrylate) and is dried at a temperature of about 90-180° C. for about 30 minutes.

5. The layered structure of claim 1, wherein after spraying an activation agent on the first coat layer, the first material transfer layer is printed on the first coat layer in a covering relationship by using water-based printing technology to render the top surface of the substrate colorful.

6. The layered structure of claim 1, further comprising an adhesive layer coated on a bottom of the first material transfer layer, and wherein the first material transfer layer is adhered to the first coat layer by using thermal printing technology, ink in the first material transfer layer deposits the predetermined inked pattern on the first coat layer and changes color of the first coat layer, and the first material transfer layer is released to render the top surface of the substrate colorful.

7. A layered structure comprising:
a substrate including a first uneven surface on a top surface;
a first material transfer layer having a predetermined inked pattern and disposed on a top surface of the substrate;
a first coat layer having a predetermined color pattern and disposed on a top surface of the first material transfer layer, the first coat layer including a second uneven surface on a top surface;
a second material transfer layer having a predetermined inked pattern and disposed on a top surface of the first coat layer; and
a second coat layer having a predetermined color pattern and disposed on a top surface of the second material transfer layer;
wherein a CNC (computer numerical control) machine is used to render the top surface of the substrate colorful.

8. The layered structure of claim 7, wherein each of the first and second coat layers is formed by using PVD (physical vapor deposition) or CVD (chemical vapor deposition), and wherein thickness of the first and second coat layers can be increased or decreased depending on requirements.

9. The layered structure of claim 7, wherein each of the first and second coat layers is PU (polyurethane) and each of the first and second coat layers is dried at a temperature of about 180° C. for about 30 minutes.

10. The layered structure of claim 7, wherein each of the first and second coat layers is PMMA (Polymethylmethacrylate) and is dried at a temperature of about 90-180° C. for about 30 minutes.

11. The layered structure of claim 7, wherein after spraying an activation agent on the substrate or the first coat layer, the first and second material transfer layers are printed on the substrate or the first coat layer in a covering relationship by using water-based printing technology to render the top surface of the substrate colorful.

12. The layered structure of claim 7, further comprising an adhesive layer coated on a bottom of each of the first and second material transfer layers, and wherein the first and second material transfer layers are adhered to the first and second coat layers respectively by using thermal printing technology, ink in each of the first and second material transfer layers deposits the predetermined inked pattern on the first and second coat layers respectively and changes color of each of the first and second coat layers, and the first and second material transfer layers are released to render the top surface of the substrate colorful.

13. A process of manufacturing a layered structure, comprising the steps of:
(a) preparing a substrate which is aluminum alloy, magnesium alloy, or plastic;
(b) using a CNC (computer numerical control) machine to move a metal brush along a predetermined direction to rub a top surface of the substrate to form a first uneven surface on the top surface of the substrate wherein hardness of the metal brush is greater than that of the substrate, and the metal brush is made of high hardness material which is alloy steel or tool steel;
(c) using the CNC machine to control a coating device for coating a first coat layer on the top surface of the substrate wherein the first coat layer has a predetermined color pattern;
(d) drying the first coat layer;
(e) using the CNC machine to move the metal brush along a predetermined direction to rub a top surface of the coat layer to form a first uneven surface on the top surface of the substrate;
(f) using the CNC machine to dispose a first material transfer layer having a predetermined inked pattern on the top surface of the coat layer;
(g) drying the first material transfer layer at a temperature of 100-150° C. for about 30 minutes;
(h) repeating steps (c) to (g) to form a second coat layer and a second material transfer layer on the first coat layer sequentially; and
(i) performing QC (quality control), packaging, and shipping.

14. The process of manufacturing a layered structure of claim 13, wherein washing is done on the substrate for removing solution and oil remained after forming the first uneven surface on the top surface of the substrate in step (b).

15. The process of manufacturing a layered structure of claim 13, wherein each of the first and second coat layers is formed by using PVD (physical vapor deposition) or CVD (chemical vapor deposition), and wherein thickness of the first and second coat layers can be increased or decreased depending on requirements.

16. The process of manufacturing a layered structure of claim 13, wherein each of the first and second coat layers is PU (polyurethane) and each of the first and second coat layers is dried at a temperature of about 180° C. for about 30 minutes.

17. The process of manufacturing a layered structure of claim 13, wherein each of the first and second coat layers is PMMA (Polymethylmethacrylate) and is dried at a temperature of about 90-180° C. for about 30 minutes.

18. The process of manufacturing a layered structure of claim 13, wherein after spraying an activation agent on the substrate or the first coat layer, the first and second material transfer layers are printed on the substrate or the first coat layer in a covering relationship by using water-based printing technology to render the top surface of the substrate colorful.

19. The process of manufacturing a layered structure of claim 13, further comprising an adhesive layer coated on a bottom of each of the first and second material transfer layers, and wherein the first and second material transfer layers are adhered to the first and second coat layers respectively by using thermal printing technology, ink in each of the first and second material transfer layers deposits the predetermined inked pattern on the first and second coat layers respectively and changes color of each of the first and second coat layers, and the first and second material transfer layers are released to render the top surface of the substrate colorful.
